(19) United States
(12) Patent Application Publication
(10) Pub. No.: US 2009/0173524 A1
(43) Pub. Date: Jul. 9, 2009

(54) DUAL DENSITY PRINTED CIRCUIT BOARD ISOLATION PLANES AND METHOD OF MANUFACTURE THEREOF

(75) Inventor: Chad W. Morgan, Mechanicsburg, PA (US)

Correspondence Address: Tyco Technology Resources, 4450 New Linden Hill Road, Suite 140, Wilmington, DE, 19808, US

(73) Assignee: Tyco Electronics Corporation, Middletown, PA (US)

(21) Appl. No.: 11/970,360

(22) Filed: Jan. 7, 2008

(51) Int. Cl. H05K 1/09; H05K 1/00; H05K 3/00

(52) U.S. Cl. 174/257; 174/250; 29/829

(57) ABSTRACT

A conductive power isolation plane for reducing interlayer cross-talk in a printed circuit board between conductive through vias on one side of the printed circuit board and conductive through vias on the other side of the printed circuit board and a method of manufacturing the same. In one embodiment, a printed circuit board includes a (1) conductive power isolation plane interlaminated within a plurality of insulating dielectric layers, (2) a first dielectric layer having a conductive through via laminated to a surface of the plurality of insulating dielectric layers, (3) a second dielectric layer having a conductive through via laminated to a surface of the plurality of insulating dielectric layers opposite the first dielectric layer and (4) a conductive ground via extending through the first dielectric layer, the plurality of insulating layers, including the conductive power isolation plane, and the second dielectric layer.

### TECHNICAL FIELD

The invention is directed, in general, to a printed circuit board and, more specifically, to a dual-density printed circuit board that is constructed to reduce inter-layer cross-talk.

### BACKGROUND

Smaller and faster electronic devices put a premium on available circuit space. As transmission speeds increase and more circuitry is crowded into a limited space, printed circuit boards quickly reach maximum capacity. In addition, significant signal integrity problems arise within crowded footprints where the circuitry that connects components contacts the printed circuit board. In short, as the density of connections increase, signal-to-signal cross-talk and other signal integrity problems increase.

One way of increasing printed circuit board capacity is to use “dual-density” printed circuit boards. A dual-density printed circuit board is constructed by laminating a dielectric substrate with conductive through-holes or vias therein to one side of an insulating dielectric layer and laminating a second dielectric substrate with conductive through-holes therein to the other side of the insulating dielectric layer. The vias on each side are plated to provide electrical connectivity, but those on one side do not have a direct electrical connection to those on the other side. A dual-density printed circuit board is similar to a sandwich where the dielectric substrates with conductive through-holes are the bread and are laminated to each side of an insulating dielectric layer which is the meat. After the dual-density printed circuit board is assembled, conductive through-holes can be drilled through the entire printed circuit board to provide further signal and ground connections. The result is that some conductive vias are stacked but are not in electrical contact. Because both sides of the board can be used independently, a dual-density printed circuit board may potentially have twice the number of connections as the traditional printed circuit board.

Dual-density printed circuit boards are known to those skilled in the pertinent art, but seldom used because of fabrication cost. However, as transfer rates and data speeds increase, the electronics industry may be forced to use them in order to supply electronic devices that meet customer requirements. In addition to an increased circuit capacity, dual-density printed circuit boards have other advantages. For example, a dual-density printed circuit board allows the use of smaller and, therefore, more vias. As a practical matter, the size of a printed circuit board via is limited by the aspect ratio of the via (i.e., the ratio of the thickness of the substrate to the diameter if the via). Generally an aspect ratio of 10 to 1 is about the most that can be expected when a via is plated in an assembled printed circuit board. Because dual-density vias are plated in the substrates before being laminated to the insulating dielectric layer, a smaller hole can be plated. Other advantages of a dual-density printed circuit board include shorter vias, shorter via stubs and, of course, increased density.

The layout of a dual-density printed circuit board most usually has conductive vias on one side of the board directly opposite conductive vias on the other side, without them being in electrical contact with each other. The close proximity of the vias to each other in a dual-density printed circuit board substantially increases the probability of cross-talk between circuits on opposite sides of the board. This cross-talk is a potentially significant limitation on the usefulness of dual-density printed circuit boards.

Accordingly, what is needed in the art is a device that will reduce cross-talk between electrical circuits on opposite sides of a dual-density printed circuit board.

### SUMMARY

To address the above-discussed,deficiencies of the prior art, one aspect of the invention provides for a printed circuit board with a conductive power isolation plane to reduce interlayer cross-talk. In one embodiment, the printed circuit board includes a (1) conductive power isolation plane interlaminated within a plurality of insulating dielectric layers, (2) a first dielectric layer having a conductive through via laminated to a surface of the plurality of insulating dielectric layers, (3) a second dielectric layer having a conductive through via laminated to a surface of the plurality of insulating dielectric layers opposite the first dielectric layer, and (4) a conductive ground via extending through the first dielectric layer, the plurality of insulating layers, including the conductive power isolation plane, and the second dielectric layer.

A method of manufacturing a dual-density printed circuit board that includes a conductive power isolation plane is also described. Also described is an aspect of the invention where an electronic circuit includes a dual-density printed circuit board that has a conductive power isolation plane.

The foregoing has outlined certain aspects and embodiments of the invention so that those skilled in the art may better understand the detailed description of the invention that follows. Additional embodiments will be described hereinafter that form the subject of the claims of the invention. Those skilled in the art should appreciate that they can readily use the disclosed aspects and embodiments as a basis for designing or modifying equivalent structures for carrying out the same purposes of the invention. Those skilled in the art should also realize that such equivalent constructions do not depart from the scope of the invention.

### BRIEF DESCRIPTION OF THE DRAWINGS

For a more complete understanding of the invention, reference is now made to the following descriptions taken in conjunction with the accompanying drawings, in which:

FIG. 1 illustrates a planar side view of a dual-density printed circuit board constructed in accordance with the invention;

FIG. 2 illustrates an isometric view of a dual-density printed circuit board constructed in accordance with the invention with a power isolation plane broken out of the stack of layers;

FIG. 3 illustrates an isometric view of a power isolation plane constructed in accordance with the invention with a pattern of openings therein that are designed to alleviate parasitic capacitance;

FIG. 4 illustrates an isometric view of electronic components in an electronic circuit mounted to a dual-density printed circuit board in accordance with the invention; and

FIG. 5 illustrates a flow chart of a method of manufacturing a dual-density printed circuit board that includes one or more power isolation planes carried out in accordance with the invention.

### DETAILED DESCRIPTION

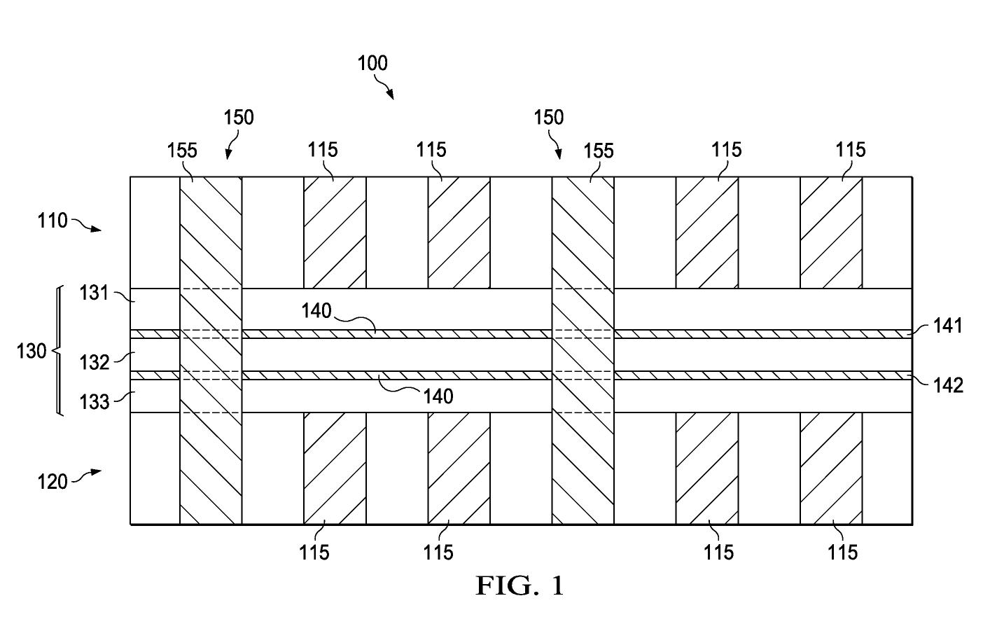

Referring initially to FIG. 1, illustrated is a planar side view of a dual-density printed circuit board 100 constructed in accordance with the invention. The illustrated dual-density printed circuit board 100 is made up of a number of layers of dielectric material laminated together. Before being laminated to the other layers, a first dielectric layer 110 with a number of conductive through vias 115 is formed. Also shown is a second dielectric layer 120 with a number of conductive through vias 115 formed therein before being laminated to the other layers. As shown in FIG. 1, the first dielectric layer 110 is laminated to insulating dielectric layer 131, which is one of a plurality of insulating dielectric layers 130. The second dielectric layer 120 is laminated to insulating dielectric layer 133 which is also one of the plurality of insulating dielectric layers 130.

The illustrated embodiment shows conductive through vias 115 in the first dielectric layer 110 located directly over conductive through vias 115 in the second dielectric layer 120. However, because of the intervening insulating dielectric layers, the conductive through vias 115 in the first dielectric layer 110 are not in electrical contact with the conductive through vias 115 in the second dielectric layer 120. Although not in electrical contact with each other, the proximity of the conductive through vias 115 in the first dielectric layer 110 with those in the second dielectric layer 120 will potentially produce cross-talk with a consequent degradation of overall circuit performance. The invention addresses this problem by inserting a conductive power isolation plane 140 between conductive through vias 115 in the first dielectric layer 110 and conductive through vias 115 in the second dielectric layer 120. Those skilled in the pertinent art will understand that the term “power isolation plane” 140 is the same thing as a “ground isolation plane”, which terms are intended to be synonymous as used herein. This conductive power isolation plane 140 may be grounded or it may be set to a given voltage, both of which embodiments are within the intended scope of the present invention. The conductive power isolation plane 140 is interlaminated between layers of the plurality of insulating dielectric layers 130. The illustrated dual-density printed circuit board shows a plurality of conductive isolation planes 140 interlaminated between the plurality of insulating dielectric layers 130. One conductive isolation plane 141 is laminated between insulating dielectric layers 131 and 132 and a second conductive isolation plane 142 is laminated between insulating dielectric layers 132 and 133.

In one embodiment, the conductive isolation plane 140 will be copper, although any suitable conductive material can be used. In one embodiment, the conductive isolation planes 141, 142 are electrically connected to a conductive ground 155 located in a conductive ground via 150 extending through the first dielectric layer 110, the plurality of insulating layers 130, including the conductive isolation planes 141, 142, and the second dielectric layer 120.

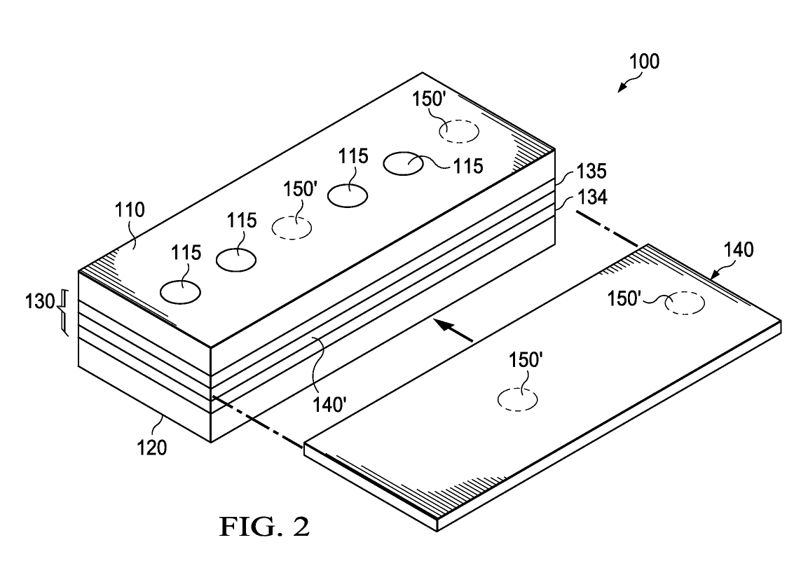

Turning now to FIG. 2, illustrated is an isometric view of a dual-density printed circuit board 100 constructed in accordance with the invention with a power isolation plane 140 broken out of the stack of layers. As pointed out above with respect to FIG. 1, the power isolation plane 140 is located within the stack of layers 110, 120, 130 which are laminated together to form a printed circuit board 100. The first dielectric layer 110 is shown with conductive vias 115 drilled before the printed circuit board 100 was laminated together. The second dielectric layer 120 also has vias (not shown) drilled prior to being laminated. The illustrated printed circuit board 100 has two insulating layers 134, 135 with a power isolation plane 140′ sandwiched between them. The illustrated power isolation plane 140 that is broken out has a solid surface; that is, its surface when laminated into the plurality of insulating layers 130 does not have a pattern of holes on its surface. After the power isolation plane 140 is laminated into the plurality of insulating layers 130, a conductive ground via 150′ is drilled and plated forming the conductive ground 155. A possible problem with a dual-density printed circuit board 100 of the type illustrated is that of parasitic capacitance. This problem is addressed by an embodiment described next.

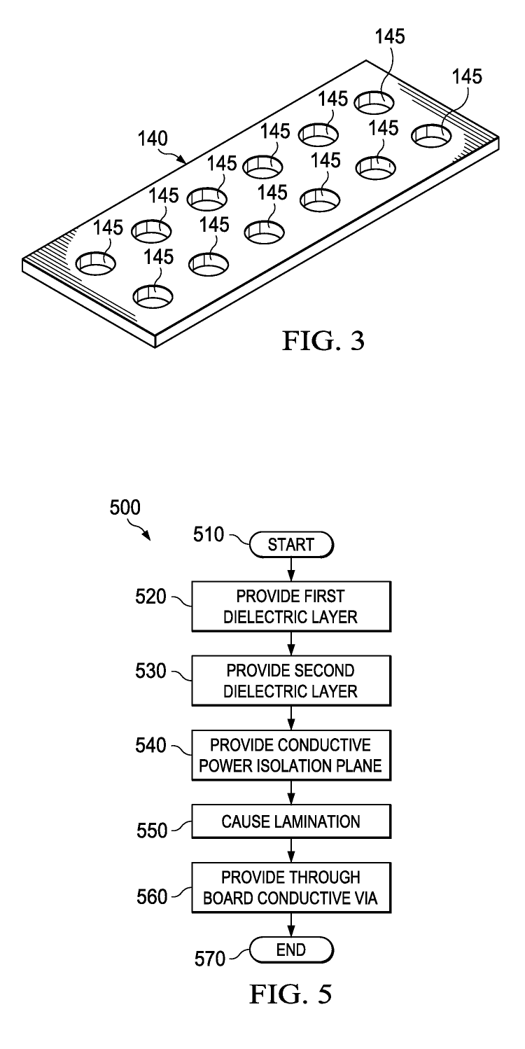

Turning now to FIG. 3, illustrated is an isometric view of a power isolation plane 140 constructed in accordance with the invention with a pattern of openings 145 therein designed to alleviate parasitic capacitance. The illustrated power isolation plane 140 can be usefully employed in those cases where a plurality of power isolation planes 140 are used and the probability of parasitic capacitance exists that would interfere with electrical circuitry. The illustrated pattern of openings 145 shows a series of circles, but the openings can assume any shape or configuration and still be within the intended scope of the invention. The actual pattern of openings 145 depends on the parasitic capacitance characteristics to be controlled.

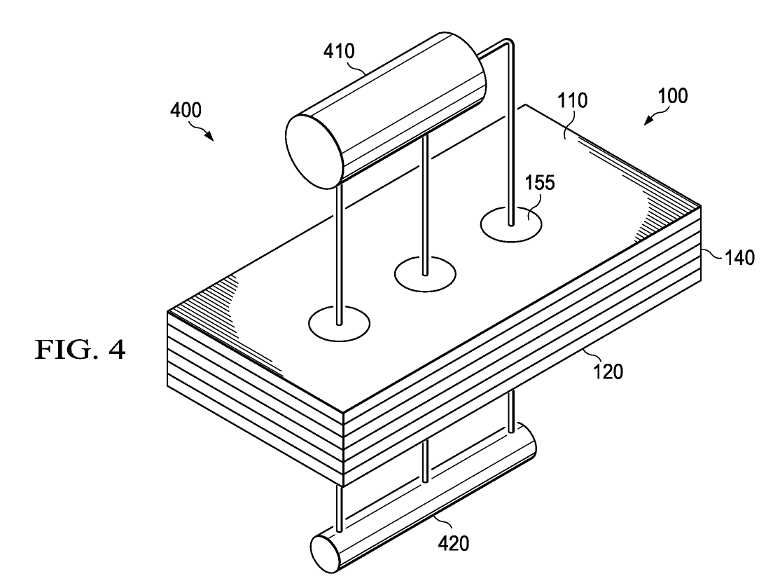

Turning now to FIG. 4, illustrated is an isometric view of electronic components 410, 420 in an electronic circuit 400 mounted to a dual-density printed circuit board 100 in accordance with the invention. One component 410 is coupled to the first dielectric layer 110 of the dual-density printed circuit board 100 while the second component is coupled to the second dielectric layer 120. The electronic component 410 mounted on the first dielectric layer 110 is electrically isolated from the component 420 mounted on the second dielectric layer 120, although they share a common conductive ground 155. Also illustrated is a conductive isolation plane 140 that prevents crosstalk between the electronic circuits or components 410, 420 on each side of the dual-density printed circuit board 100. Those skilled in the pertinent art will understand that a typical electronic circuit 400 will have many more electronic components 410, 420 than shown in FIG. 4. Two electronic components 410, 420 are shown solely for the purpose of illustrating the usefulness of a dual-density printed circuit board 100 that permits both sides of the board 100 to be used while keeping the components 410, 420 on one side electrically isolated from those on the other. The fact that a denser concentration of components 410,420 is provided for when dual-density vias 115 are employed is readily apparent for FIG. 4.

Turning now to FIG. 5, illustrated is a flow chart of a method of manufacturing 500 a dual-density printed circuit board, in accordance with the invention, that includes one or more power isolation planes. In one embodiment, the method commences with a start step 510. In a ‘provide first dielectric layer’ step 520, a dielectric layer is provided with through vias formed therein. In a ‘provide second dielectric’ layer step 530 a second dielectric layer with through vias formed therein is provided. In a ‘provide conductive power isolation plane’ step 540, a power isolation plane that will be interlaminated within a plurality of insulating dielectric layers is provided. In one embodiment, a plurality of power isolation planes will be interlaminated within the plurality of insulating dielectric layers. The power isolation plane may have either a solid surface or it may have a surface with preformed holes, both of which are within the intended scope of the invention. In one embodiment the power isolation plane is copper although any conductive material can be used and be within the intended scope of the invention.

In a ‘cause lamination’ step 550, a first dielectric layer with conductive through vias is laminated to a surface of a plurality of insulating dielectric layers having at least one power isolation plane interlaminated therein. A second dielectric layer with conductive through vias is laminated to a surface of the plurality of insulating dielectric layers opposite the first dielectric layer. In a ‘provide through board conductive via’ step 560, a via is extended through the first dielectric layer, the plurality of insulating layers, including any power isolation planes interleaved therein, and the second dielectric layer. The method concludes with an end step 570.

Although certain aspects and embodiments of the invention have been described in detail, those skilled in the art should understand that they can make various changes, substitutions and alterations herein without departing from the scope of the invention in its broadest form.

What is claimed is:

1. A printed circuit board, comprising:
a conductive power isolation plane interlaminated within a plurality of insulating dielectric layers;
a first dielectric layer having a conductive through via laminated to a surface of said plurality of insulating dielectric layers; and
a second dielectric layer having a conductive through via laminated to a surface of said plurality of insulating dielectric layers opposite said first dielectric layer.

2. The printed circuit board as recited in claim 1 wherein a conductive ground via extends through said first dielectric layer, said plurality of insulating layers, including said conductive power isolation plane, and said second dielectric layer.

3. The printed circuit board as recited in claim 2 wherein said conductive power isolation plane contacts said conductive ground via.

4. The printed circuit board as recited in claim 1 wherein said conductive power isolation plane is copper.

5. The printed circuit board as recited in claim 1 wherein said conductive power isolation plane is solid.

6. The printed circuit board as recited in claim 1 wherein said conductive power isolation plane has openings therein.

7. The printed circuit board as recited in claim 1 wherein said conductive through via in said first dielectric layer is opposite said conductive through via in said second dielectric layer.

8. The printed circuit board as recited in claim 1 wherein a plurality of said conductive power isolation plane is interlaminated within said plurality of insulating dielectric layers.

9. A method of manufacturing a printed circuit board, comprising:
provide for a conductive power isolation plane to be interlaminated within a plurality of insulating dielectric layers;
provide for a first dielectric layer having a conductive through via to be laminated to a surface of said plurality of insulating dielectric layers; and
provide for a second dielectric layer having a conductive through via to be laminated to a surface of said plurality of insulating dielectric layers opposite said first dielectric layer.

10. The method as recited in claim 9 further comprising providing a conductive ground via extending through said first dielectric layer, said plurality of insulating layers, including said conductive power isolation plane, and said second dielectric layer.

11. The method as recited in claim 10 wherein said conductive power isolation plane is in electrical contact with said conductive ground via.

12. The method as recited in claim 9 wherein said conductive power isolation plane is copper.

13. The method as recited in claim 9 wherein said conductive power isolation plane is solid.

14. The method as recited in claim 9 wherein said conductive power isolation plane has openings patterned therein.

15. The method as recited in claim 9 wherein said conductive through via in said first dielectric layer is arranged opposite said conductive through via in said second dielectric layer.

16. The method as recited in claim 9 wherein a plurality of said conductive power isolation plane is interlaminated within said plurality of insulating dielectric layers.

17. An electronic circuit, comprising:
electronic components coupled to, each side of a dual-density printed circuit board, wherein said dual-density printed circuit board includes;
a conductive power isolation plane interlaminated within a plurality of insulating dielectric layers;
a first dielectric layer having a conductive through via laminated to a surface of said plurality of insulating dielectric layers; and
a second dielectric layer having a conductive through via laminated to a surface of said plurality of insulating dielectric layers opposite said first dielectric layer.

18. The electronic circuit as recited in claim 17 further including a conductive ground via extending through said first dielectric layer, said plurality of insulating layers, including said conductive power isolation plane, and said second dielectric layer.

19. The electronic circuit as recited in claim 18 wherein said conductive power isolation plane contacts said conductive ground via.

20. The electronic circuit as recited in claim 17 wherein a plurality of said conductive power isolation plane is interlaminated within said plurality of insulating dielectric layers.
